(19) United States
(12) Patent Application Publication
(10) Pub. No.: US 2007/0081386 A1
(43) Pub. Date: Apr. 12, 2007

(54) Methods, circuits and computer program products for updating data in non-volatile memories

(76) Inventor: Jeong-Hyon Yoon, Seoul (KR)

Correspondence Address: MYERS BIGEL SIBLEY & SAJOVEC, PO BOX 37428, RALEIGH, NC, 27627, US

(21) Appl. No.: 11/516,672

(22) Filed: Sep. 6, 2006

(30) Foreign Application Priority Data
Sep. 6, 2005 (KR) 10-2005-0082496

(51) Int. Cl. G11C 16/04

(52) U.S. Cl. 365/185.11

(57) ABSTRACT

A method of updating data, which is stored in each page in a non-volatile memory with a multi-plane structure, using an external buffer, is provided. In the method, source data that will not be updated in a page in each plane of the non-volatile memory is moved to the external buffer. The source data is loaded from the external buffer to an empty page in each plane and dummy programming is performed. Update data received from a host is randomly inputted to the page to which the source data has been loaded in each plane and programming is performed.

### CROSS-REFERENCE TO RELATED APPLICATION

This application claims the priority of Korean Patent Application No. 2005-0082496, filed on Sep. 6, 2005, in the Korean Intellectual Property Office, the disclosure of which is incorporated herein in its entirety by reference.

### FIELD OF THE INVENTION

The present invention relates to non-volatile memory (NVM), and more particularly, to methods, circuits and computer program products for updating data in NVM.

### BACKGROUND

When NVM, for example, NAND flash memory, is comprised of a single level cell storing one bit of data, the NAND flash memory supports a page copy-back function. Page copy-back is a function that sets a buffer in the NAND flash memory and temporarily stores source data to be updated in the buffer. Since the NAND flash memory does not support overwriting, when existing data stored therein is updated, the data is stored in the buffer. Next, a relevant area is erased. Next, the data in the buffer is loaded and randomly input in the area, and then programming is performed.

Such page copy-back function is not supported in multi-level cell NAND flash memory that stores two bits of data. In addition, since an error often occurs while data is moved to a buffer even in single level cell NAND flash memory, the page copy-back function may be excluded from standards.

In NAND flash memory that does not support the page copy-back function and has a multi-plane structure, when data is moved in a plane, source data stored in each page is certainly moved to an external buffer and then to a target page. In this situation, when the number of planes increases or when the number of interface channels allowing a read/write operation to be simultaneously performed in a plurality of NAND flash memories increases, the size of the external buffer also increases.

For example, to update data in a NAND flash memory that has two planes in two channels, has a 2 KB page, and does not support the page copy-back function, an 8 KB external buffer is needed because page programming in multiple planes is possible only at the same page addresses in blocks on the same line. Source data is stored in the external buffer by planes and by channels. Next, update data received from a host and the source data read from the external buffer are loaded to a new page by planes and channels in order, and then programming is performed. Accordingly, when the number of channels increases, the size of the external buffer increases and data updating becomes complicated.

### SUMMARY

Embodiments according to the present invention can provide methods, circuits and computer programs for updating data in a non-volatile memory (NVM). Pursuant to these embodiments, a method of updating data stored in a non-volatile memory (NVM) with a multi-plane structure can include moving source data that will not be updated in a page in each plane of the NVM to an external buffer, loading the source data from the external buffer to the planes of an empty page of the NVM and performing dummy programming to provide a partial empty page, and randomly inputting update data received from a host to each plane of the partial empty page performing actual programming.

### BRIEF DESCRIPTION OF THE DRAWINGS

FIG. 1 (a) illustrates a NAND flash memory array using the present invention;

FIG. 1 (b) illustrates a page separated from the NAND flash memory array shown in FIG. 1 (a);

FIG. 2 (a) illustrates the structure of a NAND flash memory having two planes;

FIG. 2 (b) illustrates page programming procedures for the respective two planes shown in FIG. 2(a);

FIG. 3 illustrates the changes in data stored in a NAND flash memory when the data is updated through a single channel;

FIG. 4 is a block diagram of a circuit for updating data according to some embodiments of the present invention;

FIG. 5 is a flowchart of a method of updating data in a single-channel NAND flash memory according to some embodiments of the present invention;

FIG. 6 illustrates the internal structures of respective NAND flash memories when data is updated through two channels; and

FIG. 7 is a flowchart of a method of updating data in NAND flash memories using a plurality of channels according to some embodiments of the present invention.

### DESCRIPTION OF EMBODIMENTS ACCORDING TO THE INVENTION

Embodiments of the present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

As will be appreciated by one of skill in the art, the present invention may be embodied as a method, data processing system, and/or computer program product. Accordingly, the present invention may take the form of an entirely hardware embodiment, an entirely software embodiment or an embodiment combining software and hardware aspects all generally referred to herein as a “circuit” or “module.” Furthermore, the present invention may take the form of a computer program product on a computer usable storage medium having computer usable program code embodied in the medium. Any suitable computer readable medium may be utilized including hard disks, CD ROMs, optical storage devices, a transmission media such as those supporting the Internet or an intranet, or magnetic storage devices.

The present invention is described below with reference to flowchart illustrations and/or block diagrams of methods, systems and computer program products according to embodiments of the invention. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing circuit to produce a machine, such that the instructions, which execute via the processor of the computer or other programmable data processing circuit, create means for implementing the functions/acts specified in the flowchart and/or block diagram block or blocks.

These computer program instructions may also be stored in a computer readable memory that can direct a computer or other programmable data processing circuit to function in a particular manner, such that the instructions stored in the computer readable memory produce an article of manufacture including instruction means which implement the function/act specified in the flowchart and/or block diagram block or blocks.

The computer program instructions may also be loaded onto a computer or other programmable data processing circuit to cause a series of operational steps to be performed on the computer or other programmable circuit to produce a computer implemented process such that the instructions which execute on the computer or other programmable circuit provide steps for implementing the functions/acts specified in the flowchart and/or block diagram block or blocks.

It is to be understood that the functions/acts noted in the blocks may occur out of the order noted in the operational illustrations. For example, two blocks shown in succession may in fact be executed substantially concurrently or the blocks may sometimes be executed in the reverse order, depending upon the functionality/acts involved. Although some of the diagrams include arrows on communication paths to show a primary direction of communication, it is to be understood that communication may occur in the opposite direction to the depicted arrows.

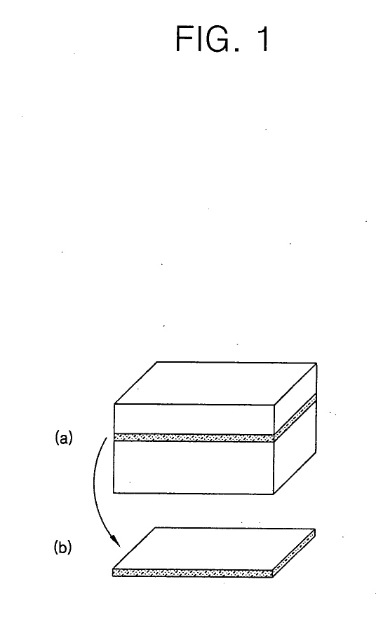

FIG. 1 (a) illustrates a NAND flash memory array using the present invention. FIG. 1(b) illustrates a page separated from the NAND flash memory array shown in FIG. 1(a).

The NAND flash memory shown in FIG. 1(a) corresponds to a single device. The single device includes a 2 KB block comprised of 128 pages. Each page is comprised of (2 K+64) bytes. A page in a block is accessed by a row address and a position in the page is designated by a column address. The single device has a multi-plane structure and does not support a page copy-back function.

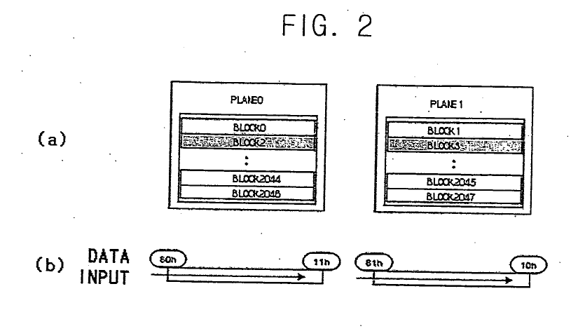

FIG. 2(a) illustrates the structure of a NAND flash memory having two planes. Referring to FIG. 2(a), each plane includes a 1 KB block. Plane 0 includes blocks having an even numbered address and plane 1 includes blocks having an odd numbered address.

FIG. 2(b) illustrates page programming procedures for the respective two planes shown in FIG. 2(a). When page programming is performed on the two planes 0 and 1, only the same pages in blocks on the same line are supported. When block erasing is performed on the two planes 0 and 1, only blocks on the same line are erased. In detail, in the planes 0 and 1, a shaded block 2 and a shaded block 3 are second blocks in the respective planes 0 and 1 and are located on the same line. In other words, page programming in two planes is possible at the same page addresses in blocks on the same line.

In an embodiment of the present invention, page program commands for the plane 0 include a data input command 80h for loading source data to a relevant page in the plane 0 and a dummy program command 11h for finishing data loading. Page program commands for the plane 1 include a data input command 81h with respect to the plane 1 and an actual program command 10h for writing loaded data to a page. In addition, when data is stored in a part of a page, a random data input command 85h for receiving other data is used to store the data in the rest part of the page.

To program data using the above-described commands, conventionally, the commands 80h and 11h are certainly followed by the commands 81h and 10h according to a flash translation layer (FTL) protocol so that data is loaded to the plane 0 for dummy program and then the data is loaded to the plane 1 for actual programming.

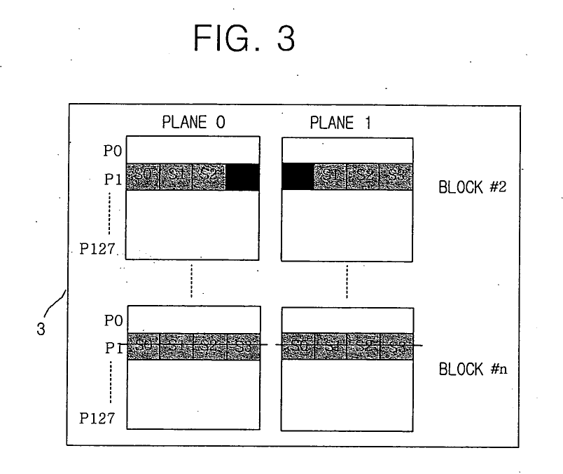

FIG. 3 illustrates the changes in data stored in a NAND flash memory when the data is updated through a single channel. Referring to FIG. 3, among data stored in a NAND flash memory 3, data at a sector S3 in the plane 0 and data at a sector S0 in the plane 1, which are located at a page P1 of an n-th block BLOCK #n, are updated. For this updating, among data in the page P1 of the n-th block BLOCK #n, data that are not updated, i.e., data at sectors S0, S1, and S2 are stored in an external buffer (not shown) and is then loaded to a random page P1 of a random empty block, e.g., a second block BLOCK #2. Update data is randomly input from a host (not shown) to a position of the sector S3 in page P1 for dummy program. Next, another update data is input from the host to the page P1 of the second block in the plane 1, data corresponding to sectors S1, S2, and S3 are randomly input from the external buffer to the page P1 of the second block in the plane 1, and then actual program is performed.

For the above-described updating procedure, commands are input as follows after data located at the page P1 of the n-th block is moved to the external buffer: 80h-address(plane 0, second block, page P1)-data(S0, S1, S2)-address(plane 0, second block, page P1, sector S3)-new data(S3)-11h; and 81h-address(plane 1, second block, page P1) new data(S0)-85h-address(plane 1, second block, page P1, sector S1)-data(S1, S2, S3)-10h, where the address(x) is a command designating an address of a position corresponding to “x”, the data(y) is a command for loading data “y” from the external buffer, and the new data(z) is a command for receiving new data “z” from the host.

When the above-described updating procedure is used for a plurality of channels, since a plurality of NAND flash memories are simultaneously programmed through the plurality of channels according to the FTL protocol, the size of the external buffer needs to be multiplied. In other words, for a single channel, the size of the external buffer is determined as (a page size x the number of planes). When a plurality of channels are used, the size of the external buffer is further multiplied by the number of channels.

In some embodiments according to the present invention, dummy programming is sequentially performed on non-update data in NAND flash memories, and then update data is received from a host and actual programming is substantially simultaneously performed in the NAND flash memories. Accordingly, the size of an external buffer is maintained constant regardless of the number of channels.

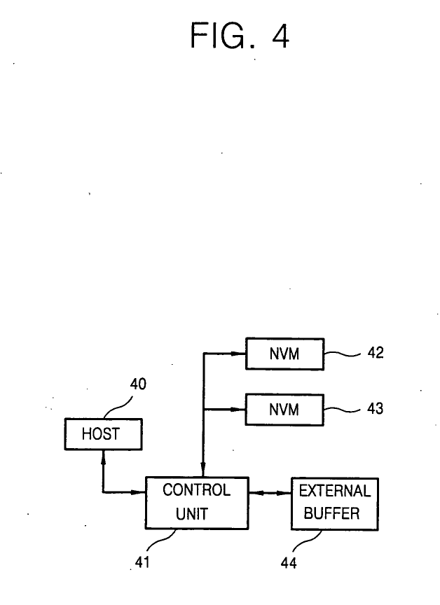

FIG. 4 is a block diagram of a circuit for updating data according to an embodiment of the present invention. The cirucit includes a host 40, a control unit 41, a first non-volatile memory (NVM) 42, a second NVM 43, and an external buffer 44. For clarity of the description, only two NVMs 42 and 43 are illustrated, but the present invention is not restricted thereto and may include more memories.

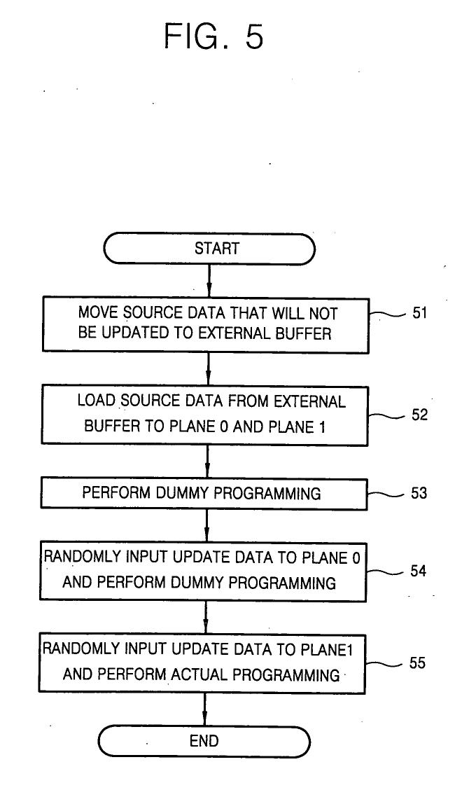

When a single channel is used, that is, when only one of the first and second NVMs 42 and 43 is connected to the control unit 41, the operations of the cirucit shown in FIG. 4 will be described with reference to FIG. 5, which is a flowchart of a method of updating data in a single-channel NAND flash memory according to an embodiment of the present invention.

In response to a data update request from the host 40, the control unit 41 moves data that will not be updated (hereinafter, referred to as source data) in a page of each plane to the external buffer 44 in operation 51. The control unit 41 loads source data(non-update data) from the external buffer 44 to a random page in any empty block of each plane in operation 52 and performs dummy programming in operation 53. Here, the size of the external buffer 44 may be defined as (the number of planes x the size of source data that will not be updated in a page).

Next, the control unit 41 randomly inputs update data received from the host 40 to the corresponding page of each plane and then performs programming. In detail, the control unit 41 randomly inputs update data received for the plane 0 from the host 40 to the corresponding page of the plane 0 and performs dummy programming in operation 54. In addition, the control unit 41 randomly inputs update data received for the plane 1 from the host 40 to the corresponding page of the plane 1 and performs actual programming in operation 55.

In the above-described method, commands are input as follows after the source data is stored in the external buffer 44: 80h-address(plane 0)-data(S0, S1, S2)-11h; 80h(or 81h)-address(plane 1)-data(S1, S2, S3)-11h; 85h-address(plane 0)-new data(S3)-11h; and 85h-address(plane 1)-new data(S0)-10h.

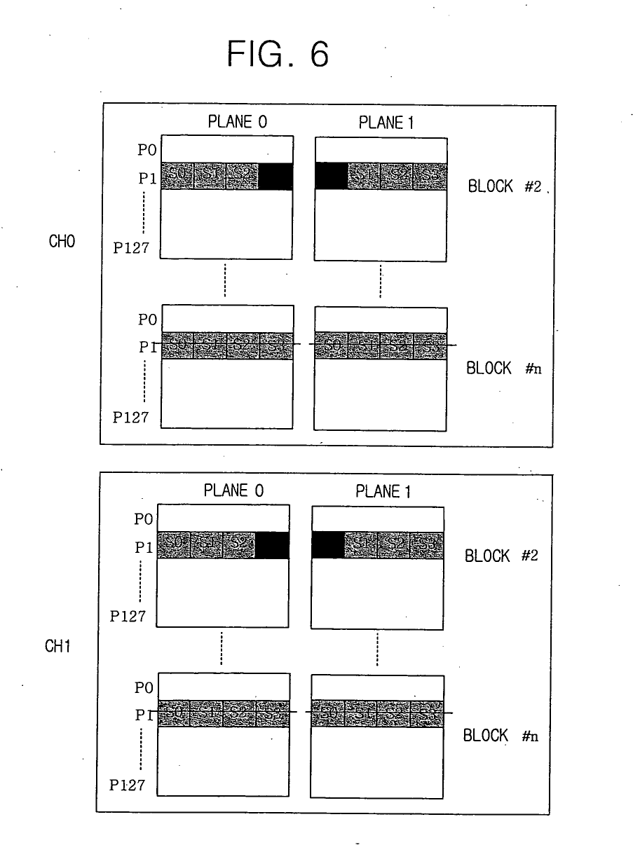

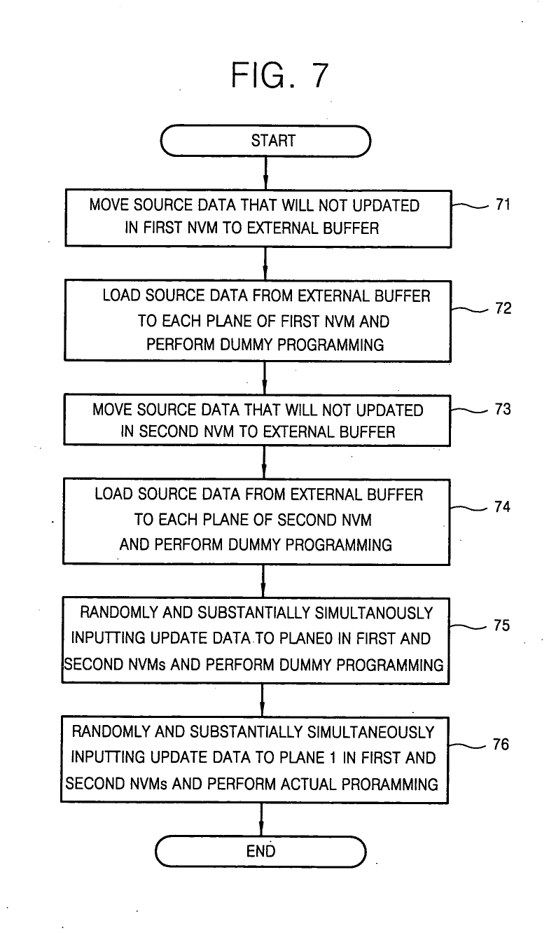

FIG. 6 illustrates the internal structures of the respective NAND flash memories 42 and 43 when data is updated through two channels. Referring to FIG. 6, among data stored in the NAND flash memories 42 and 43, data in the sector S3 in the plane 0 and data in the sector S0 in the plane 1, which are located at the page P1 in the n-th block, are updated. A method of updating data in the NVMs 42 and 43 through two channels will be described with reference to FIG. 7.

In response to an update request for data stored in the first and second NVMs 42 and 43 from the host 40, the control unit 41 moves source data that will not be updated in a relevant page of each plane included in the first NVM 42 to the external buffer 44 in a random order in operation 71. The control unit 41 loads the source data stored in the external buffer 44 to a random page in an empty block of each plane included in the first NVM 42 and performs dummy programming in operation 72. Next, the control unit 41 moves source data that will not be updated in a relevant page of each plane included in the second NVM 43 to the external buffer 44 in operation 73. The control unit 41 loads the source data stored in the external buffer 44 to a random page in an empty block of each plane included in the second NVM 43 and performs dummy programming in operation 74.

After completing the data loading, the control unit 41 randomly and substantially simultaneously inputs update data received from the host 40 to the page of each plane included in the first and second NVMs 42 and 43 and performs programming. In detail, the control unit 41 randomly and substantially simultaneously inputs update data received from the host 40 to the page of the plane 0 in the first and second NVMs 42 and 43 and performs dummy programming in operation 75. When two or more planes are present, update data is randomly and substantially simultaneously input to the corresponding page of all planes except a last plane and dummy programming is performed.

Next, the control unit 41 randomly and substantially simultaneously inputs update data received from the host 40 to the corresponding page of the plane 1 or the last plane in the first and second NVMs 42 and 43 and performs actual programming in operation 76.

In the above method, commands are input as follows. After source data with respect to channel 0 is stored in the external buffer 44, commands 80h-address(plane 0)-data(S0, S1, S2)-11h and 80h-address(plane 1)-data(S1, S2, S3)-11h are performed so that the source data(non-update data) is loaded from the external buffer 44 to a page of an empty block and dummy programming is performed. Next, after source data with respect to channel 1 is stored in the external buffer 44, commands 80h-address(plane 0)-data(S0, S1, S2)-11h and 80h-address(plane 1)-data(S1, S2, S3)-11h are performed so that the source data is loaded from the external buffer 44 to a page of an empty block and dummy programming is performed. After the data loading from the external buffer 44 is completed, commands 85h-address(plane 0)-new data(S3)-11h and 85h-address(plane 1)-new data(S0)-10h are substantially simultaneously performed with respect to the channels 0 and 1 so that the corresponding pages in the first and second NVMs 42 and 43 is programmed.

In some embodiments according to the present invention, data loading for source data is performed as many times as the number of planes included in each NVM, random input and dummy programming for update data is repeated in each plane except a last plane simultaneously in all NVMs, and random input and actual programming for the update data is performed in the last plane in all NVMs.

In some embodiments according to the present invention, when data stored in NVMs of multiple channels that do not support a page copy-back function is updated, loading and dummy programming is performed on source data that will not be updated with respect to each channel, and random input and actual programming is performed with respect to update data in all NVMs substantially simultaneously. As a result, data in multi-channel NVMs can be updated with an external buffer having only a size needed for data updating through a single channel. Accordingly, it may not be necessary to increase the size of the external buffer when the number of channels increases.

What is claimed:

1. A method of updating data stored in a non-volatile memory (NVM) with a multi-plane structure, the method comprising:
moving source data that will not be updated in a page in each plane of the NVM to an external buffer;
loading the source data from the external buffer to the planes of an empty page of the NVM and performing a first dummy programming to provide a partial empty page; and
randomly inputting update data received from a host to each plane of the partial empty page and performing random programming.

2. The method of claim 1, wherein the performing random programming comprises:
randomly inputting first data among the update data to all planes of the partial empty page except a last plane and performing a second dummy programming; and
randomly inputting second data among the update data to the last plane and performing actual programming.

3. The method of claim 2, wherein a size of the external buffer comprises a size of the source data in the page multiplied by a number of the planes.

4. A method of updating data stored in a non-volatile memory (NVM) with a multi-plane structure, the method comprising:
(a) moving source data that is not be updated from each plane of a page included in a first non-volatile memory to an external buffer;
(b) loading the source data from the external buffer to each plane of an empty page in the first non-volatile memory and performing a first dummy programming to provide a partial empty page;
repeating steps (a) and (b) for remaining non-volatile memories; and
randomly and simultaneously inputting update data received from a host to each plane in the partial empty page included in all of the non-volatile memories and performing random programming.

5. The method of claim 4, wherein the performing random programming comprises:
randomly inputting first data among the update data to all planes of the partial empty page except a last plane and performing a second dummy programming; and
randomly inputting second data among the update data to the last plane of the partial empty page and performing actual programming.

6. The method of claim 5, wherein a size of the external buffer comprises a size of the source data in the page multiplied by a number of the planes independent of the number of channels.

7. A circuit in a non-volatile memory, the circuit comprising:
a plurality of non-volatile memories each comprising a plurality of planes and storing data in each page in the planes;
an external buffer provided outside the non-volatile memories; and
a control unit sequentially performing moving source data that will not be updated in a page of each plane included in each of the non-volatile memories to the external buffer, loading the source data from the external buffer to an empty page in each plane, and performing dummy programming, and randomly and substantially simultaneously inputting update data received from a host to the page to which the source data has been loaded in each plane in all of the non-volatile memories and performing programming.

8. The circuit of claim 7, wherein the control unit randomly and substantially simultaneously inputs first data among the update data to the page to which the source data has been loaded in all planes except a last plane in all of the non-volatile memories, performs dummy programming, and randomly and substantially simultaneously inputting second data among the update data to the page of the last plane to which the source data has been loaded in all of the non-volatile memories and performing actual programming.

9. The circuit of claim 8, wherein the external buffer has a size defined as (a size of the source data in the page x the number of the planes).

10. A computer program product for updating data stored in a non-volatile memory (NVM) with a multi-plane structure, the computer program product comprising:
a computer readable medium having computer readable program code embodied therein, the computer readable program product comprising:
computer readable program code configured to move source data that will not be updated in a page in each plane of the NVM to an external buffer;
computer readable program code configured to load the source data from the external buffer to the planes of an empty page of the NVM and performing a first dummy programming to provide a partial empty page; and
computer readable program code configured to randomly input update data received from a host to each plane of the partial empty page and performing random programming.

11. The computer program product of claim 10, wherein the computer readable program code configured to perform random programming comprises:
computer readable program code configured to randomly input first data among the update data to all planes of the partial empty page except a last plane and performing a second dummy programming; and
computer readable program code configured to randomly input second data among the update data to the last plane and performing actual programming.

12. The computer program product of claim 11, wherein a size of the external buffer comprises a size of the source data in the page multiplied by a number of the planes.

13. A method of updating data stored in a non-volatile memory (NVM) with a multi-plane structure, the method comprising:
performing a dummy programming operation of the source data to planes of the NVM to provide a partial empty page; and
randomly input updated data received from a host to the planes of the partial empty page; and
performing actual programming of the updated data in the NVM.
